(19) United States
(12) Patent Application Publication
(10) Pub. No.: US 2010/0085708 A1
(43) Pub. Date: Apr. 8, 2010

(54) HIGH-EFFICIENCY, FLUID-COOLED UPS CONVERTER

(75) Inventors: James K. Martin, Galena, OH (US); Mark C. McMaster, Menlo Park, CA (US); Norman Chow, Milipitas, CA (US); Bruce R. Conway, La Honda, CA (US); Richard G. Brewer, Foster City, CA (US); Girish K. Upadhya, Austin, TX (US); Stephen Sillato, Westerville, OH (US)

Correspondence Address: HARNESS, DICKEY & PIERCE, P.L.C., P.O. BOX 828, BLOOMFIELD HILLS, MI, 48303, US

(73) Assignee: Liebert Corporation, Columbus, OH (US)

(21) Appl. No.: 12/574,445

(22) Filed: Oct. 6, 2009

Related U.S. Application Data
(60) Provisional application No. 61/103,465, filed on Oct. 7, 2008.

(51) Int. Cl. H05K 7/20; F28D 15/00; F28F 7/00

(52) U.S. Cl. 361/696; 165/104.28; 165/104.33; 165/121; 361/701; 361/699

(57) ABSTRACT

An interruptible power supply (UPS) may include direct cooling for various components of the UPS that generate heat. The direct cooling may be part of a cooling system that directs the generated heat to the ambient environment external to the room or building housing the UPS such that the heat load of the UPS places a minimal or zero load on the air-conditioning system for the room within which the UPS is located. The cooling system can utilize multiple cooling loops to transfer the heat from the heat-generating components of the UPS to the ambient environment.

### CROSS-REFERENCE TO RELATED APPLICATIONS

This application claims the benefit of U.S. Provisional Application No. 61/103,465, filed on Oct. 7, 2008. The entire disclosure of the above application is incorporated herein by reference.

### FIELD

The present disclosure relates generally to uninterruptible power supplies and, more particularly, to cooling uninterruptible power supply converters.

### BACKGROUND

The statements in this section merely provide background information related to the present disclosure and may not constitute prior art.

High-power uninterruptible power supplies (UPS) are used in supplying power to a facility, or areas of a facility. A high-power UPS typically has a one mega-volt-amp (MVA) capacity or above. Power is supplied from an electric utility substation to the UPS which conditions the power. The UPS has a source of back-up power, such as a battery bank, flywheel, fuel cell, generator, or the like, that provides power in the event of an interruption of power supplied by the utility.

The UPS includes a variety of components that generate heat. Currently, the heat load of these components is dumped into the air in the room within which the UPS is disposed. The heat dumped into the room is removed by the air-conditioning system that conditions the air in the room. The use of the room air-conditioning system can be inefficient. Additionally, the use of the room air-conditioning system may limit the size of the UPS or the number of UPSs that can be utilized therein.

### SUMMARY

This section provides a general summary of the disclosure, and is not a comprehensive disclosure with its full scope or all of its features.

A UPS according to the present invention may include direct cooling for various components of the UPS that generate heat. The direct cooling may be part of a cooling system that directs the generated heat to the ambient environment external to the room or building housing the UPS such that the heat load of the UPS places a minimal or zero load on the air-conditioning system for the room within which the UPS is located. The cooling system can utilize multiple cooling loops to transfer the heat from the heat-generating components of the UPS to the ambient environment. The ability to transfer the heat from the UPS to the ambient environment may allow for any size UPS or number of UPSs to be utilized in a room regardless of the capabilities of the air-conditioning system for that room.

A method of transferring heat generated in an uninterruptible power supply to an environment external to the room or building housing the uninterruptible power supply, the uninterruptible power supply having a plurality of heat-generating components within a cabinet. The method includes generating heat in the uninterruptible power supply with the plurality of heat-generating components. A first liquid-heat-transfer fluid is pumped through a first cooling circuit with a first liquid pump. Heat is transferred from a first one of the heat-generating components in the cabinet to a first medium. The first medium is in direct heat-conducting relation with the first heat-generating component. The first heat-generating component is one of a rectifier, an inverter, and a switch. Heat is transferred from the first medium to the first heat-transfer fluid. Heat is further transferred from the first heat-transfer fluid to the environment external to the room or building housing the uninterruptible power supply while by-passing the air flow flowing through the room housing the uninterruptible power supply.

An uninterruptible power supply system includes a cabinet and a plurality of heat-generating components in the cabinet. The heat-generating components include a rectifier, an inverter, a switch and at least one transformer. The heat-generating components generate heat during operation. A first heat-transfer medium is in direct heat-conducting relation with at least one of the heat-generating components. A first cooling circuit includes a first heat-transfer fluid and a first flow-generating device generating a flow of the first heat-transfer fluid through the first cooling circuit. A first heat-transfer flow path between the first medium and the first cooling circuit transfers heat from the first medium to the first heat-transfer fluid. A second heat-transfer flow path between the first cooling circuit and an ambient environment external to the room or building housing the cabinet transfers heat from the first heat-transfer fluid to the ambient environment.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a simplified schematic representation of a UPS and a cooling system for same according to the present invention;

FIG. 2 is a schematic representation of the removal of the heat generated by the UPS within a room according to the present invention;

FIG. 3 is a schematic representation of another cooling system for a UPS according to the present invention;

FIG. 4 is a schematic representation of yet another cooling system for a UPS according to the present invention;

FIG. 5 is a schematic representation of a UPS with another cooling system according to the present invention;

FIG. 6 is a schematic representation of a UPS with another cooling system according to the present invention;

FIG. 7 is a schematic representation of a UPS with another cooling system according to the present invention;

FIG. 8 is a schematic representation of a UPS with another cooling system according to the present invention;

FIG. 9 is a schematic representation of a UPS with another cooling system according to the present invention;

FIG. 10 is a schematic representation of a UPS with another cooling system according to the present invention;

FIG. 11 is a schematic representation of a UPS and a cooling system according to the present invention wherein the cooling system is external to the UPS; and

FIG. 12 is a schematic representation of a UPS and cooling system according to the present invention wherein the cooling system is integral with the UPS.

### DETAILED DESCRIPTION

Example embodiments will now be described more fully with reference to the accompanying drawings.

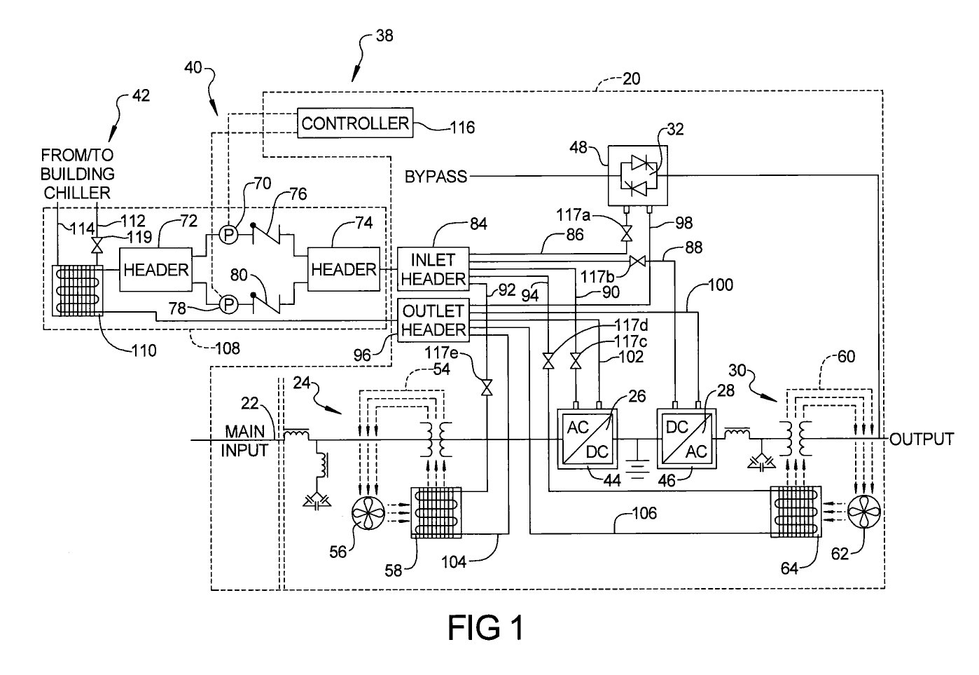

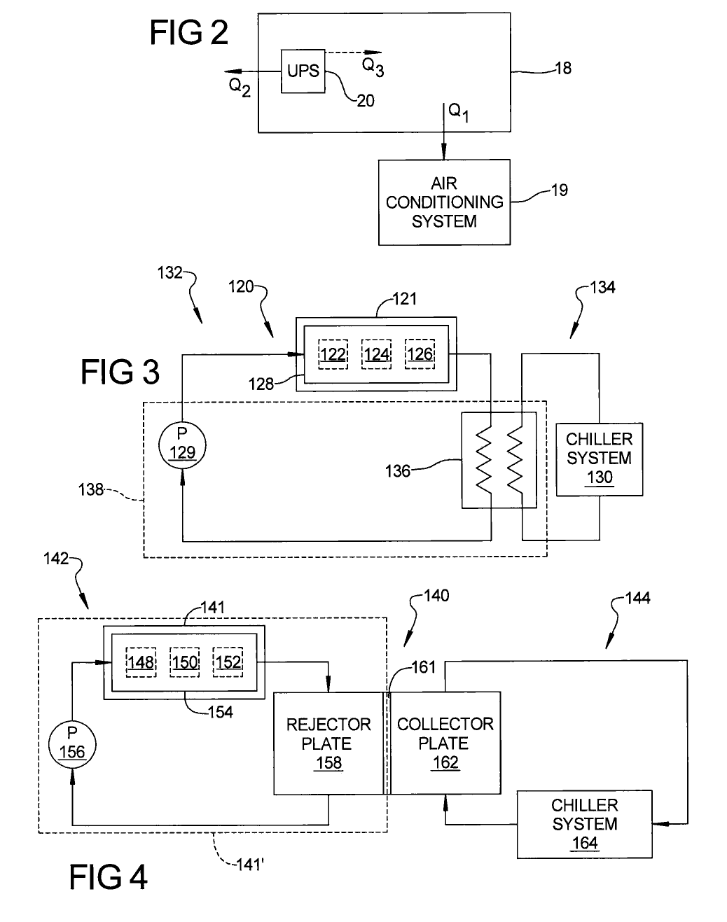

Referring to FIGS. 1 and 2, a simplified schematic of an exemplary high-power UPS 20 which can utilize a fluid cooling system 38 according to the present teachings is shown. UPS 20 may be in a cabinet or housing such that UPS 20 can be provided as a single integral unit that can be shipped to a customer. UPS 20 may be located in a room 18 which may have the air therein conditioned by an air-conditioning system 19. Fluid cooling system 38 may be utilized to discharge the heat generated by UPS 20 to the ambient environment exterior to room 18, as described below.

UPS 20 has a main power feed/input 22 that is coupled to the input of an input transformer generally indicated at 24. Input transformer 24 has a secondary coupled to an input of a rectifier 26. An output of rectifier 26 is coupled to an input of inverter 28. An output of inverter 28 is coupled to a primary of an output transformer generally indicated at 30, and the secondary of output transformer 30 can be coupled to the power distribution system (not shown) of the facility within which UPS 20 is utilized. Output transformer 30 can boost the voltage from inverter 28 to the desired output voltage, such as 480 VAC by way of non-limiting example. A bypass switch 32, such as a static switch by way of non-limiting example, when closed, bypasses UPS 20 and connects the facility's power distribution system directly to a bypass source, such as to the power feed from a utility substation.

Input transformer 24, rectifier 26, inverter 28, output transformer 30, and static switch 32 can represent the major heat-generating assemblies of UPS 20. For example, when UPS 20 is a 2-MVA system, total system losses can be in the range of about 90-126 Kw, by way of non-limiting example. The input transformer losses can be in the range of about 18-36 Kw; rectifier losses can be about 18 Kw; inverter losses can be about 36 Kw; static switch losses can be about 18 Kw; and output transformer losses can be in the range of about 18-36 Kw, by way of non-limiting examples. Input transformer 24 can have from about 1% to about 2% loss; rectifier 26 can have about a 1% loss; inverter 28 can have losses of about 2%; output transformer 30 can have losses of about 1% to about 2%; and static switch 32 can have losses of about 1%. These losses and values are merely exemplary in nature and are provided herein for purposes of illustration only.

For each watt of heat energy generated by components of UPS 20, additional energy is required to remove the heat from the room in which the UPS 20 is operated. Using a typical air-conditioning system, approximately 0.33 watts of energy is required to remove each watt of heat generated.

To improve the efficiency of the heat removal from UPS 20, the present teachings disclose multiple cooling systems that can facilitate heat removal from UPS 20 without dumping all of the heat load into the air-conditioning system utilized for the room in which UPS 20 is located.

In a preferred embodiment, as shown in FIG. 1, cooling system 38 is a two-stage cooling system. The first stage is a closed-loop, pump-driven cooling system and is generally indicated with reference indicia 40. The second stage may be a chiller system associated with the facility within which UPS 20 is to be utilized and is generally indicated with reference indicia 42. The chiller system is operable to transfer heat from cooling system 40 to the ambient environment exterior to the room within which UPS 20 is located, as described below.

Cooling system 40 is integral with UPS 20 and may include components that are both internal and external to the cabinet that forms UPS 20. Cooling system 40 contains a heat-transfer fluid (i.e., a coolant), such as water or a volatile fluid, such as a refrigerant by way of non-limiting example. One exemplary suitable refrigerant includes R134a. Cooling system 40 pumps the heat-transfer fluid therethrough to remove heat from UPS 20 and discharge the heat to the ambient environment through the second stage cooling system 42, which may be the chiller system for the facility within which UPS 20 is located, by way of non-limiting example. The heat-transfer fluid in cooling system 40 is not compressed in a refrigeration cycle. Rather, the heat-transfer fluid is a liquid that is pumped through cooling system 40. During the transferring of heat to the heat-transfer fluid (absorption of heat) from the various components of UPS 20, however, the heat-transfer fluid may evaporate to be a two-phase mixture, possibly predominantly in a gaseous phase. It should be appreciated that in some embodiments, cooling system 40 may be a vapor compression cooling system that utilizes a compressor instead of the pump and may also include an expansion device. In that case, the heat-transfer fluid may be a refrigerant, volatile fluid or the like, by way of non-limiting example, and can be compressed and change phase. The heat-transfer fluid can absorb heat from UPS 20 and transfer (discharge) the heat to the coolant flowing through cooling system 42 which may subsequently discharge the heat to the ambient environment.

To facilitate the heat transfer with the various components of UPS 20, the components can be in heat-transferring relation with a cold plate. For example, rectifier 26 can be in heat-transferring relation with cold plate 44, inverter 28 in heat-transferring relation with cold plate 46, and static switch 32 in heat-transferring relation with cold plate 48. The heat-transferring relation of the components with the cold plates may be through conduction heat transfer. Cold plates 44, 46, 48 include a plurality of channels that extend therethrough and are in heat-transfer relation with the component coupled thereto. The heat-transfer fluid may flow through the channels to absorb heat from the associated components. The structure of the channels can be configured to have sufficient surface area to allow the heat-transfer fluid to evaporate and remove heat from the component coupled to the associated cold plate. Preferably, for normal operating conditions, the heat-conducting fluid exits the associated cold plates in a two-phase mixture in a predominantly gaseous phase. It should be appreciated, however, that the heat-transfer fluid may not change state (i.e., remain in the liquid state) or may entirely change state from a liquid to a gas when removing heat from the component associated with the cold plate through which the heat-transfer fluid is flowing.

The internal structure of the cold plate does not have to consist solely of channels, but offer sufficient heat transfer surface area while not unacceptably increasing the fluid pressure drop. For example, a collection of pillars or posts may be used. Porous structures creating controlled or random three-dimensional flow paths could also be used. Exemplary porous structures could be made from metal foam, or sintered metal powder, or a stack of patterned sheets of metal bonded together, by way of non-limiting example.

To remove heat from input transformer 24 and output transformer 30, a three-stage, heat-removal process can be utilized. The heat is first removed from the associated transformer to an air flow flowing thereacross, which is subsequently transferred to cooling system 40 for subsequent discharge to the ambient by cooling system 42. Specifically, to remove heat from input transformer 24, an air flow 54 can be induced across input transformer 24 by a fan 56 and directed across a heat exchanger 58 through which the heat-transfer fluid of cooling system 40 flows. Air flow 54 is thereby operable to extract heat from input transformer 24 and subsequently transfer the extracted heat into the heat-transfer fluid flowing through cooling system 40 via heat exchanger 58. Similarly, output transformer 30 can be cooled by an air flow 60 that is induced therethrough by a fan 62 which further directs air flow 60 across a heat exchanger 64. The heat-transfer fluid of cooling system 40 flows through heat exchanger 64. Air flow 60 extracts heat from output transformer 30 and transfers the extracted heat to the heat-transfer fluid flowing through cooling system 40 via heat exchanger 64.

To supply the heat-transfer fluid to the various cold plates 44, 46, 48 and heat exchangers 58, 64, cooling system 40 includes a primary liquid pump 70 that is connected between a supply header 72 and a discharge header 74. A check valve 76 can be disposed between pump 70 and discharge header 74 to prevent backflow of the heat-transfer fluid. A secondary liquid pump 78 and secondary check valve 80 can be disposed between supply header 72 and discharge header 74 in parallel with primary pump 70 and check valve 76. Secondary pump 78 and check valve 80 provide redundancy to ensure uninterrupted operation of cooling system 40. While headers 72, 74, pumps 70, 78, and valves 76, 80 are shown as being external to the cabinet that contains UPS 20, it should be appreciated that one or more of these components may be located internal to the cabinet that defines UPS 20.

Discharge header 74 directs the heat-transfer fluid to an inlet header 84. Inlet header 84 provides separate flows of heat-transfer fluid to the various components of UPS 20 that are being cooled therewith. Inlet header 84 communicates with supply lines 86, 88, 90, 92, 94 that communicate with the inlets of cold plates 48, 46, 44 and heat exchangers 58, 64, respectively. Supply lines 86, 88, 90, 92, 94 can thereby supply the heat-transfer fluid from inlet header 84 to the associated cold plate or heat exchanger in a parallel flow arrangement. In some embodiments, the flow of the heat-transfer fluid can be a serial flow through multiple components. In some embodiments, the flow of the heat-transfer fluid can be both serial and parallel flow through the components.

Cooling system 40 includes an outlet header 96 that is operable to receive and accumulate the heat-transfer fluid flows discharged by the cold plates and heat exchangers. Outlet header 96 communicates with return lines 98, 100, 102, 104, 106 that communicate with the outlets of cold plates 48, 46, 44 and heat exchangers 58, 64, respectively. Inlet header 84 and supply lines 86, 88, 90, 92, 94 can thereby supply heat-transfer fluid to cold plates 48, 46, 44 and heat exchangers 58, 64 which are then discharged and returned to outlet header 96 through return lines 98, 100, 102, 104, 106, respectively.

Cooling system 42, as stated above, may be associated with the chiller system for the facility within which UPS 20 is utilized. As used herein, the chiller system refers to a cooling system associated with the facility and provides a second heat-transfer fluid (coolant) that can absorb heat and discharge the heat to the ambient environment external to the room or building housing the UPS. The ambient external environment may be the air or subterranean earth, by way of non-limiting example. The coolant can absorb heat from another heat-transfer fluid to allow the heat generated by the UPS to be transferred to the ambient environment exterior to the facility. Such chiller systems are known in the art and may include, by way of non-limiting example, a cooling tower or other type of chilling device operable to reduce the temperature of the coolant and discharge the heat to the ambient environment. Another chiller system, by way of non-limiting example, may include an underground pipe system wherein the temperature of the coolant flowing through the underground pipes is reduced as the heat is transferred to the ambient environment, which in this case is subterranean earth. Another chiller system, by way of non-limiting example, may also include dry coolers to reduce the temperature of the coolant and transfer the heat to the ambient environment. The coolant flowing through the chiller system may be water, glycol, or mixtures thereof, by way of non-limiting example.

The heat-transfer fluid of cooling system 40 received in outlet header 96 flows to a heat exchanger 110. Heat exchanger 110 can be a component of cooling system 42 and be pre-existing or can be part of cooling system 40 and provided along with UPS 20 (internally or externally). Within heat exchanger 110, the heat-transfer fluid of cooling system 40 flows and transfers heat to the coolant of cooling system 42 which also flows therethrough. Heat exchanger 110 includes an input line 112 and an output line 114 that allows the coolant of cooling system 42 to flow into and out of heat exchanger 110 in heat-transferring relation to the heat-transfer fluid of cooling system 40. The heat transferred to the coolant of cooling system 42 is subsequently discharged through the chiller system to the ambient environment, as known in the art.

In this manner, cooling system 40 is operable to pump a plurality of flows of heat-transfer fluid in parallel with one another to remove heat from input transformer 24, rectifier 26, inverter 28, output transformer 30, and static switch 32. The removal of heat therefrom is facilitated through the use of either cold plates 44, 46, 48 or heat exchangers 58, 64. The use of a heat-transfer fluid that can utilize evaporative cooling to absorb the heat, which is subsequently discharged to the coolant utilized in the chiller system of the facility, can advantageously increase the efficiency of the heat removal from UPS 20. Furthermore, close to 100% of the losses associated with the heat generation of the components of UPS 20 may thereby be captured with the heat-transfer fluid and subsequently transferred into the building chiller system.

Referring to FIG. 2, UPS 20 is shown disposed in a room 18. An air-conditioning system 19 is operable to remove heat Q₁ from room 18. UPS 20 utilizes cooling system 40 to remove heat Q₂ from UPS 20 and transfer the heat Q₂ outside of room 18. In some embodiments, substantially all of the heat generated by UPS 20 is removed from room 18 by cooling system 40. In other embodiments, cooling system 40 removes a majority of the heat Q₂ generated by UPS 20 while a minority of the heat Q₃ (shown in phantom) generated by UPS 20 is dumped into room 18 and subsequently removed from room 18 by air-conditioning system 19 as part of heat Q₁. The ability of cooling system 40 to transfer heat Q₂ generated by UPS 20 to outside of room 18 reduces the cooling load on air-conditioning system 19. Furthermore, this ability may allow for larger or additional UPSs 20 to be utilized in room 18 while having a minimal impact on the cooling load on air-conditioning system 19. As a result, increases to the cooling load capacity of air-conditioning system 19 may be avoided when a UPS is located in room 18 regardless of the number or size.

Cooling system 40 can be controlled to coordinate the heat removal therefrom with the heat removal from room 18 within which UPS 20 is disposed. A controller 116 can control the operation of pumps 70, 78 to initiate and terminate their operation. In one embodiment, the cooling system 40 can become operational whenever air-conditioning system 19 is operating. Pumps 70, 78 can be operated to provide a continuous flow of the heat-transfer fluid when air-conditioning system 19 is active. In some embodiments, cooling system 40 can be operated continuously while air-conditioning system 19 is cycled on and off. In this embodiment, controller 116 can command pump 70, 78 to provide a continuous flow of the heat-transfer fluid. In some embodiments, cooling system 40 can be turned on/off as needed regardless of the status of the operation of air-conditioning system 19. In this embodiment, controller 116 will command operation of pump 70, 78 as needed to provide the desired heat removal from UPS 20.

Controller 116 can receive various input signals (not shown) that are used to command the operation of pump 70, 78. By way of non-limiting example, controller 116 can receive signals indicative of the operation of the air-conditioning system 19, the temperature of the heat-transfer fluid flowing through inlet header 84 and/or outlet header 96, the temperature of the various cold plates 44, 46, 48 or the associated components, rectifier 26, inverter 28 and bypass switch 32 and/or the temperature of input and output transformers 24, 30. Additionally, it should be appreciated that one or more flow regulators 117a-e can be utilized to regulate the flow through the various cold plates 44, 46, 48 and heat exchangers 58, 64. Flow regulators 117a-e may be associated with supply lines 86, 88, 90, 92, 94, as shown, or with return lines 98, 100, 102, 104, 106. Flow regulators 117a-e can be a solenoid valve or other type of device for regulating flow in cooling system 40, by way of non-limiting example. Flow regulators 117a-e can maintain a desired flow through the various components to achieve a desired cooling of UPS 20. Flow regulators 117a-e can be responsive to commands received from controller 116. Flow regulators 117a-e can operate so as to limit the maximum flow to each of the associated components. This action can balance the flow so that if the heat loading of the various components is different, the flows can be adjusted to accommodate the differing loads. In some embodiments, a regulator 119 may also be utilized to control the flow of coolant through heat exchanger 110 to coordinate the heat removal achieved by cooling system 40. Regulator 119 may be responsive to signals from controller 116 and controller 116 may be used to control the coolant flow into and out of heat exchanger 110. In some embodiments, controller 116 can receive an input signal indicative of the dew point temperature of the air in and/or around UPS 20. Controller 116 can utilize this information and adjust operation of cooling system 40 to keep the temperature of the heat-transfer fluid and/or the components of UPS 20 above the dew point.

Thus, a cooling system according to the present teachings can be utilized to remove heat from UPS 20 at the source of the heat generation. The close proximity of the heat removal to the source reduces and/or minimizes the amount of heat that is transferred from the UPS to the room within which the UPS is located. The cooling system can be interconnected to the chiller system of the facility within which the UPS is being utilized to allow the transferring of the heat generated by the UPS to the coolant of the chiller system. The heat can then be dumped to the ambient environment. The interconnection to the chiller system may allow the UPS to be packaged and shipped with the associated cooling system and related components already therein or coupled thereto. The UPS can then be easily connected to a fluid flow from the chiller system and allow the removal of the heat from the UPS to the ambient exterior environment.

Referring now to FIG. 3, a simplified schematic representation of another embodiment of a cooling system 120, which can be used to remove heat generated by the various components of a UPS 121 according to the present teachings, is shown. Cooling system 120 is similar to cooling system 38 discussed above. As such, only the main differences between cooling system 120 and cooling system 38 may be described herein. Cooling system 120 is a two-stage cooling system. The first stage is a closed-loop, pump-driven cooling system and is generally indicated with reference indicia 132. The second stage may be associated with a chiller system associated with the facility within which UPS 121 is to be utilized and is generally indicated with reference indicia 134. Cooling system 134 is operable to transfer heat from cooling system 132 to the ambient environment exterior to the room within which UPS 121 is located, as described below.

Cooling system 132 is integral with UPS 121 and may include components that are both internal and external to the cabinet that forms UPS 121. In cooling system 132, heat is removed from various insulated-gate bipolar transistors (IGBT) modules 122, 124, 126. IGBT modules 122, 124, 126 are representative of various components that can be included in UPS 121. For example, IGBT modules 122, 124, 126 can be representative of a rectifier, an inverter, and a static switch that are utilized in UPS 121. Cooling system 132 may utilize a single primary cold plate 128 that each IGBT module 122, 124, 126 is in heat-transferring relation with. Primary cold plate 128 is in thermal contact with the heat-spreading surface of IGBT modules 122, 124, 126 or with the devices themselves. Cooling system 132 includes a pump 129 that pumps a heat-transfer fluid, such as water or a refrigerant, therethrough. The refrigerant, by way of non-limiting example, can be R134a. Pump 129 may be external (as shown) or internal to the cabinet that forms UPS 121. The heat-transfer fluid is pumped through cooling system 132 and is not compressed with a compressor. It should be appreciated that in some embodiments, cooling system 132 may be a vapor compression cooling system that utilizes a compressor instead of the pump and may also include an expansion device. In that case, the heat-transfer fluid may be refrigerant, volatile fluid, and the like, by way of non-limiting example and can be compressed and change phase.

Cold plate 128 includes a plurality of channels therein that are structured to provide sufficient surface area to allow the heat-transfer fluid flowing therethrough to evaporate and extract heat from IGBT modules 122, 124, 126. Preferably, the heat-transfer fluid exiting cold plate 128 is a two-phase mixture in a predominantly gaseous phase. It should be appreciated, however, that the heat-transfer fluid may not change state (i.e., remain in the liquid state) or may entirely change state from a liquid to a gas when removing heat from IGBT modules 122, 124, 126. Cooling system 132, like cooling system 40, can be utilized in conjunction with a chiller system for the facility in which UPS 121 is utilized to facilitate the removal of the heat generated by UPS 121 and transferring the generated heat to the ambient environment.

Cooling system 132 is in heat-exchange relation with cooling system 134 which may be part of the chiller system for the facility within which the UPS 121 is located. Specifically, the heat-transfer fluid in cooling system 132 can travel through a heat exchanger 136 in heat-transferring relation to the coolant of cooling system 134 which also flows therethrough. In this manner, cooling system 132 can transfer the heat removed from IGBT modules 122, 124, 126 to the coolant flowing through cooling system 134 for discharge to the ambient environment with the chiller system 130. Heat exchanger 136 can be provided along with UPS 121 for simple connection to an existing chiller system 130 of the facility in which UPS 121 is utilized. It should be appreciated that heat exchanger 136 may be internal to, external of, or integral with the cabinet that forms UPS 121. It should also be appreciated that chiller system 130 may include one or more pumps to pump the coolant flow through cooling system 134 and heat exchanger 136.

While cooling system 132 is shown having a single cold plate 128 in heat-transferring relation with each IGBT module 122, 124, 126, it should be appreciated that multiple cold plates may be used such that each IGBT module 122, 124, 126 (or other heat-generating components of UPS 121) is associated with its own individual cold plate or shares a cold plate with one or more other IGBT modules (or components). It should further be appreciated that while a cold plate is shown, heat pipes or other heat-transfer features can also be employed between the IGBT modules and the heat-transfer fluid. Moreover, it should also be appreciated that an air flow can be induced across the transformers in UPS 121 and be transferred to the heat-transfer fluid in cooling system 132 for a subsequent transfer to the coolant in cooling system 134 and discharged to the ambient environment through chiller system 130 in a three-stage heat removal process, as discussed above with reference to cooling system 40 and UPS 20. Accordingly, multiple heat-generating components of a UPS can be in heat-transferring relation with the same cold plate with the heat-transferring fluid of the cooling system flowing therethrough.

Referring now to FIG. 4, another embodiment of a cooling system 140 according to the present teachings is schematically illustrated. Cooling system 140 is similar to cooling systems 38 and 132 discussed above with reference to FIGS. 1 and 3. As such, only the main differences may be discussed. In particular, cooling system 140 utilizes a two-step process to transfer heat from a UPS 141 to the ambient environment outside of the room within which UPS 141 is located. Cooling system 140 is a two-stage cooling system. The first stage is a closed-loop, pump-driven cooling system and is generally indicated with reference indicia 142. The second stage may be associated with a chiller system of the facility within which UPS 141 is to be utilized and is generally indicated with reference indicia 144. Cooling system 144 is operable to transfer heat from cooling system 142 to the ambient environment exterior to the room within which UPS 141 is located, as described below.

Cooling system 142 is integral with UPS 141 and may include components that are both internal and external to the cabinet that forms UPS 141. In cooling system 142, heat is removed from various IGBT modules, in a manner similar to that discussed above with reference to cooling system 132. Specifically, cooling system 142 is operable to extract heat from IGBT modules 148, 150, 152 which may be representative of various components that can be included in UPS 141, such as a rectifier, an inverter, and a static switch. Cooling system 142 may utilize a single primary cold plate 154 that each IGBT module 148, 150, 152 is in heat-transferring relation with. Primary cold plate 154 is in thermal contact with the heat-spreading surface of the IGBT modules or with the devices themselves. Cooling system 142 includes a pump 156 that pumps a heat-transfer fluid, such as water or a refrigerant, therethrough. The refrigerant, by way of non-limiting example, can be R134a. Pump 156 may be external (as shown) or internal to the cabinet that forms UPS 141. The heat-transfer fluid is pumped through cooling system 142 and is not compressed with a compressor. Pump 156 also pumps the heat-transfer fluid through a primary rejecter plate 158. Preferably, primary rejecter plate 158 is located outside of the cabinet of UPS 141. It should be appreciated, however, that primary rejecter plate 158 may be located within the cabinet that defines UPS 141 or integral therewith. It should also be appreciated that in some embodiments, cooling system 142 may be a vapor-compression cooling system that utilizes a compressor instead of the pump and may also include an expansion device. In that case, the heat-transfer fluid may be a refrigerant, volatile fluid, and the like, by way of non-limiting example, and can be compressed and change phase.

Cold plate 154 includes a plurality of channels therein that are structured to provide sufficient surface area to allow the heat-transfer fluid flowing therethrough to evaporate and extract heat from IGBT modules 148, 150, 152. Preferably, the heat-transfer fluid exiting cold plate 154 is a two-phase mixture in a predominantly gaseous phase. It should be appreciated, however, that the heat-transfer fluid may not change state (i.e., remain in the liquid state) or may entirely change state from a liquid to a gas when removing heat from IGBT modules 148, 150, 152. Cooling system 142, like cooling system 40, can be utilized in conjunction with a chiller system for the facility in which UPS 141 is utilized to facilitate the removal of the heat generated by UPS 141 and transferring the generated heat to the ambient environment.

Secondary cooling system 144 may be associated with the chiller system 164 for the facility in which UPS 141 is utilized. Cooling system 144 routes a coolant through a secondary collector plate 162, which is in heat-transfer relation with primary rejecter plate 158. A thermal interface material (TIM) 161 may be used between rejecter plate 158 and collector plate 162. TIM 161 is a highly thermally conductive material, such as a highly conductive grease, by way of non-limiting example, that facilitates the heat transfer between rejecter plate 158 and collector plate 162. In this manner, heat from the heat-transfer fluid in cooling system 142 may be transferred to the coolant flowing through cooling system 144 without an exchange of fluid across the thermal interface. Cooling system 144 may utilize a pump (not shown) to pump the coolant through collector plate 162 and onto chiller system 164.

It should be appreciated that while cooling system 142 is shown having a single cold plate 154 in heat-transferring relation with IGBTs modules 148, 150, 152 that multiple cold plates can be used such that each IGBT module 148, 150, 152 (or other heat-generating component of UPS 141) is associated with its own individual cold plate or shares a cold plate with one or more other IGBT modules (or components). It should further be appreciated that while a cold plate is shown, heat pipes or other heat-transfer features can also be employed between the IGBT modules and the heat-transfer fluid. Moreover, it should also be appreciated that an air flow can be induced across the transformers in UPS 141 and be transferred to the heat-transfer fluid in cooling system 142 for subsequent transfer to the coolant in cooling system 144 for discharge to the ambient environment, as discussed above with reference to cooling system 40 and UPS 20. Accordingly, multiple heat-generating components of a UPS can be in heat-transferring relation with the same cold plate with the heat-transferring fluid of the cooling system flowing therethrough.

Thus, in cooling system 140, the two-step process allows the heat removed from the UPS 141 to be carried outside the room within which the UPS 141 is disposed and transferred to the coolant of cooling system 144. This heat removal process reduces and/or eliminates a cooling load placed on the air-conditioning system that is used to cool the room or building within which the UPS 141 is located, as described above with reference to cooling system 40.

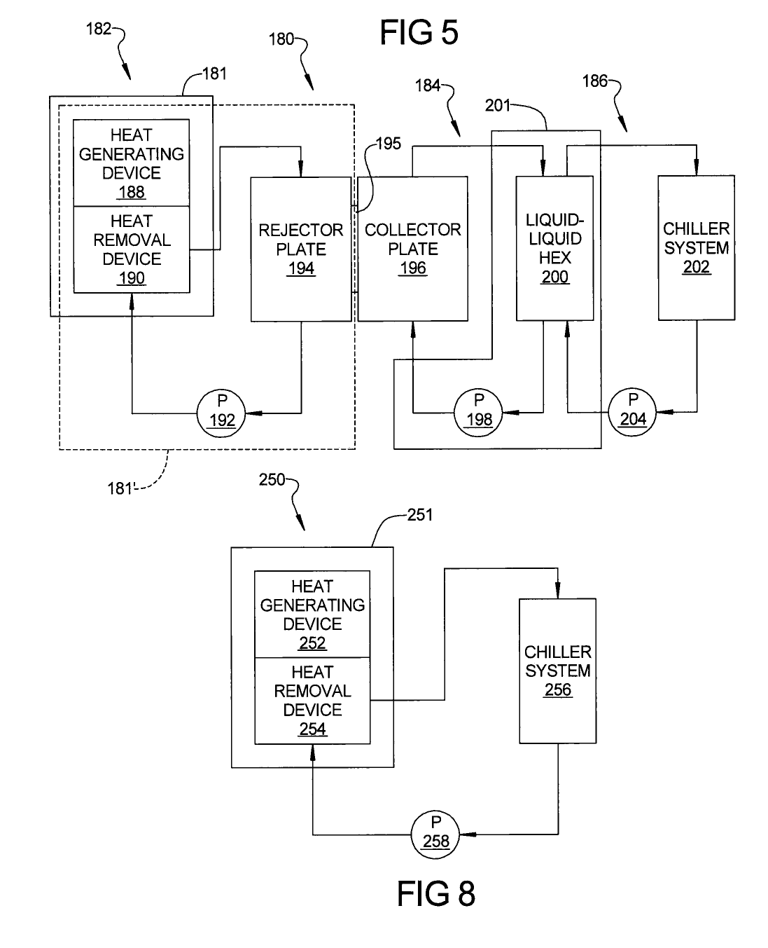

Referring now to FIG. 5, a simplified schematic representation of still another cooling system 180, which can be used to remove heat from the various components of a UPS 181 according to the present teachings, is shown. In cooling system 180, a three-step process to transfer heat from UPS 181 to the coolant flowing through the chiller system for the facility within which UPS 181 is located is utilized. Cooling system 180 includes a first or primary closed-loop cooling system 182 that is in heat-transfer relation with a secondary closed-loop cooling system 184 which is in heat-transfer relation with a final cooling system 186 associated with chiller system 202.

Primary cooling system 182 is operable to extract heat from one or more (only one shown) heat-generating devices (components) 188 of UPS 181 which are in heat-transfer relation with one or more (only one shown) heat-removal devices 190. Heat-removal devices 190 can include one or more cold plates that are in heat-transfer relation with the heat-generating components of UPS 181 and can be arranged in parallel or in series or a combination of both, as discussed above. Primary cooling system 182 includes a primary heat-transfer fluid, such as water or a refrigerant by way of non-limiting example. A pump 192 circulates the primary heat-transfer fluid through heat-removal device 190 and through a primary rejecter plate 194. Primary rejecter plate 194 and/or pump 192 can be located outside, as shown, or within (not shown) the cabinet that contains UPS 181. Preferably, primary rejecter plate 194 is located outside of the cabinet. Preferably, pump 192 is located external to the cabinet that contains UPS 181. Preferably, the primary heat-transfer fluid remains in a single phase of liquid throughout the entire flow path of primary cooling system 182. It should be appreciated that in some embodiments, primary cooling system 182 can be a vapor compression cooling system that utilizes a compressor instead of the pump and may also include an expansion device. In that case, the primary heat-transfer fluid (e.g., refrigerant, volatile fluid, and the like, by way of non-limiting example) can be compressed and change phase.

Secondary cooling system 184 is a closed-loop cooling system that routes a secondary heat-transfer fluid through a secondary collector plate 196 which is in heat-transfer relation with primary rejecter plate 194. A TIM 195 can be disposed between primary rejecter plate 194 and secondary collector plate 196. In this manner, heat from the primary heat-transfer fluid can be transferred to the secondary heat-transfer fluid flowing through secondary cooling system 184. The secondary heat-transfer fluid can be a refrigerant or water, by way of non-limiting example. A pump 198 circulates the secondary heat-transfer fluid through secondary collector plate 196 and through a heat exchanger 200 in heat-transferring relation with the coolant of cooling system 186, which may be the coolant of the chiller system 202 that services the facility within which UPS 181 is utilized. Preferably, the secondary heat-transfer fluid remains in a single liquid phase throughout secondary cooling system 184. Heat exchanger 200 can be a liquid-liquid heat exchanger. In this manner, heat from the primary heat-transfer fluid can be transferred to the secondary heat-transfer fluid and onto the coolant flowing through final cooling system 186. Final cooling system 186 may include a pump 204 that pumps the coolant through heat exchanger 200 and to chiller system 202. It should be appreciated that in some embodiments, secondary cooling system 184 can be a vapor compression cooling system that utilizes a compressor instead of the pump and may also include an expansion device. In that case, the secondary heat-transfer fluid (e.g., refrigerant, volatile fluid, and the like, by way of non-limiting example) can be compressed and change phase.

Thus, in cooling system 180, heat is removed from heat-generating device 188 of UPS 181 by heat-removal device 190 and transferred to the primary heat-transfer fluid flowing through primary cooling system 182. The heat transferred to the primary heat-transfer fluid is transferred to a secondary heat-transfer fluid flowing through secondary cooling system 184. The heat transferred to the secondary heat-transfer fluid flowing through secondary cooling system 184 is transferred to the coolant from chiller system 202 which is flowing through final cooling system 186. This process allows the heat removed from UPS 181 to be carried outside the cabinet and room within which UPS 181 is disposed and discharged to the ambient environment.

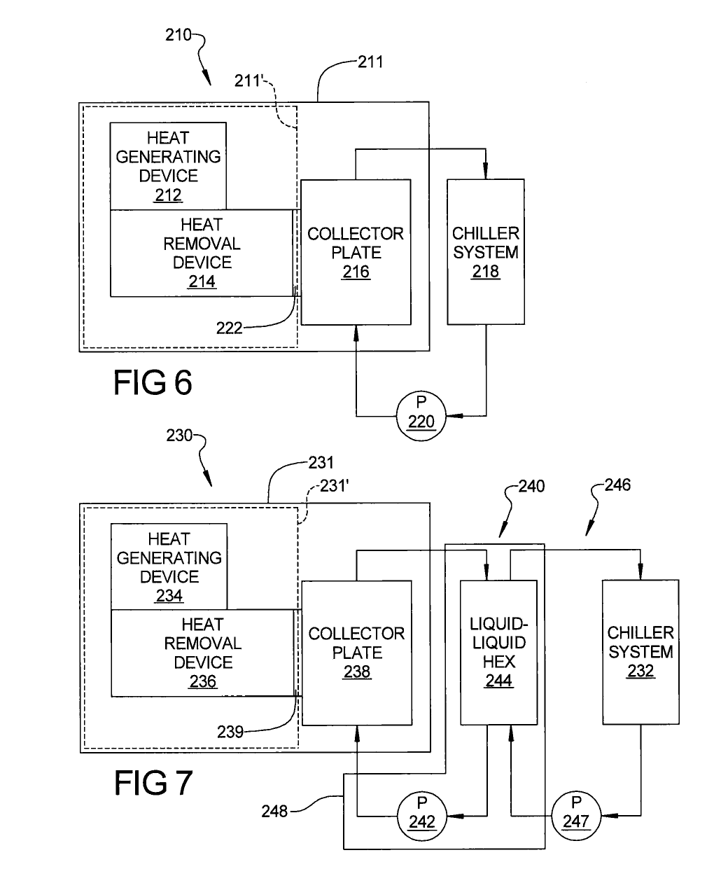

Referring now to FIG. 6, another cooling system 210 according to the present teachings is schematically illustrated. In cooling system 210, one or more (only one shown) of the heat-generating devices (components) 212 of UPS 211 are in heat-transfer relation, such as heat-conducting relation, with one or more heat-removal devices 214. Heat-removal device 214 can be one or more solid heat sinks or heat pipes, by way of non-limiting example. Heat-removal device 214 is in heat-conducting relation with a collector plate 216 through which coolant from chiller system 218, which services the facility within which UPS 211 is utilized, flows. Heat-removal device 214 and/or secondary collector plate 216 may be located within the cabinet of UPS 211, as shown, or, in other configurations, can be integral therewith or external thereto. For example, is some configurations, heat-removal device 214 may extend through the cabinet that forms UPS 211, while secondary collector plate 216 is external to the cabinet. A pump 220 circulates coolant from chiller system 218 through collector plate 216. A TIM 222 can be disposed between heat-removal device 214 and collector plate 216. Thus, in cooling system 210, heat is removed from heat-generating devices 212 of UPS 211 by heat-removal device 214 and transferred to the coolant flowing through collector plate 216. This process allows the heat generated in UPS 211 to be removed from UPS 211 and transferred outside the cabinet and room within which UPS 211 is disposed and discharged to the ambient environment.

Referring now to FIG. 7, still another cooling system 230 according to the present teachings is schematically illustrated. Cooling system 230 is similar to cooling system 210, with the main difference being the addition of an intermediate cooling system 240, as described below. As such, not all details of cooling system 230 may be described. In cooling system 230, a three-step process to transfer heat from UPS 231 to the coolant flowing through the chiller system 232 for the facility within which UPS 231 is located is utilized. In cooling system 230, one or more (only one shown) heat-generating devices (components) 234 of UPS 231 is in heat-transferring relation, such as heat-conducting relation, with one or more (only one shown) heat-removal devices 236. Heat-removal devices 236 can be solid heat sinks and heat pipes, by way of non-limiting example. Heat-removal devices 236 are in heat-transferring relation, such as heat-conducting relation, with a collector plate 238 of a closed-loop, pump-driven cooling system 240. A TIM 239 can be disposed between heat-removal device 236 and collector plate 238. Cooling system 240 includes a pump 242 that can pump a heat-transfer fluid, such as water or refrigerant, by way of non-limiting example, through collector plate 238 and through a heat exchanger 244 in heat-conducting relation with the coolant of cooling system 246, which may be part of chiller system 232 that services the facility within which UPS 231 is utilized. Preferably, the heat-transfer fluid remains in a single liquid phase throughout cooling system 240. Heat exchanger 244 between cooling system 240 and cooling system 246 may be a liquid-liquid heat exchanger. A pump 246 can circulate the coolant through heat exchanger 244 and back to chiller system 232.

Thus, in cooling system 230, heat from heat-generating devices 234 of UPS 231 is transferred through heat-removal device 236 into collector plate 238, into the heat-transfer fluid flowing through cooling system 240 and into the coolant flowing through cooling system 246. This process allows the heat removed from UPS 231 to be carried outside the cabinet and room within which UPS 231 is disposed and transferred to the coolant that flows through chiller system 232 and discharged to the ambient environment. The components of cooling system 240, along with heat-removal device 236, can be entirely or partially located inside or outside the cabinet that contains UPS 231. It should be appreciated that in some embodiments, cooling system 240 can be a vapor compression cooling system that utilizes a compressor instead of the pump and may also include an expansion device. In that case, the heat-transfer fluid (e.g., refrigerant, volatile fluid, and the like, by way of non-limiting example) can be compressed and change phase.

Referring now to FIG. 8, another cooling system 250 according to the present teachings is schematically illustrated. In cooling system 250, one or more (only one shown) heat-generating devices (components) 252 of the UPS 251 are in heat-transfer relation with one or more (only one shown) heat-removal devices 254 which are in heat-transfer relation with coolant flowing from chiller system 256 that services a facility within which UPS 251 is located. A pump 258 circulates coolant from chiller system 256 through heat-removal device 254 to remove the heat from heat-generating devices 252 and discharges the heat to the ambient environment through chiller system 256. Heat-removal device 254 can be a cold plate, as described above, by way of non-limiting example. Multiple heat-removal devices 254 can be arranged in parallel or in series or a combination of both, as described above. Pump 258 may be external to, as shown, or internal of the cabinet of UPS 251.

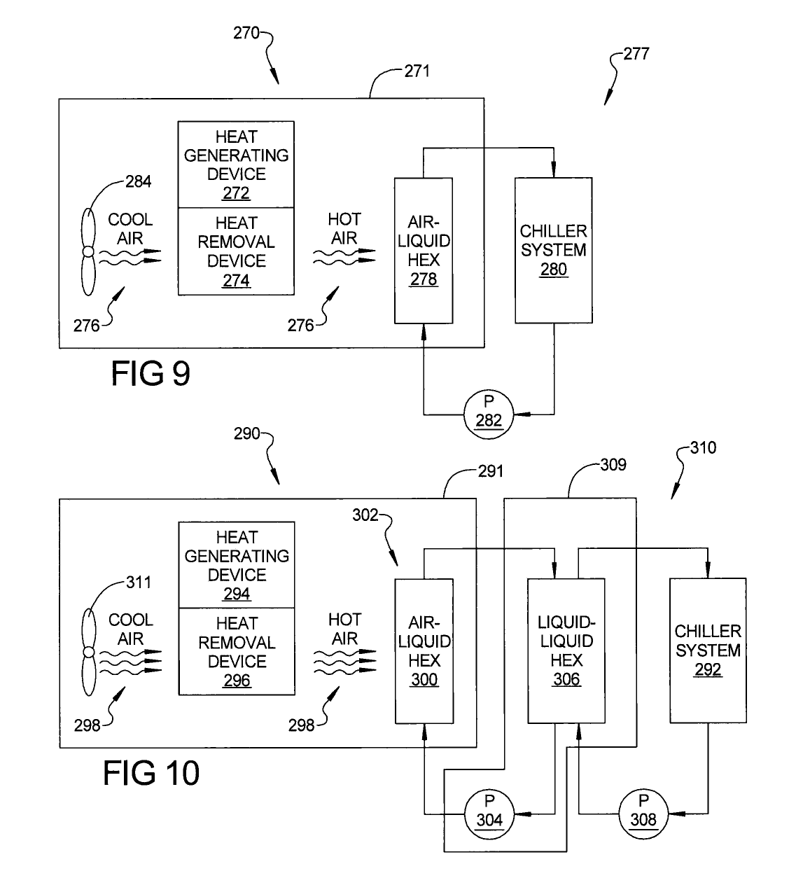

Referring now to FIG. 9, another cooling system 270 according to the present teachings is schematically illustrated. In cooling system 270, one or more (only one shown) heat-generating devices (components) 272 of the UPS 271 are in heat-transfer relation, such as heat-conducting relation, with one or more (only one shown) heat-removal devices 274. In this embodiment, heat-removal devices 274 can be heat sinks (with or without fins), a heat pipe, and the like, by way of non-limiting example. Heat-removal devices 274 are in heat-transfer relation with an air flow 276. Heat-removal device 274 transfers heat from heat-generating device 272 into air flow 276 which is subsequently transferred to coolant in cooling system 277 that flows through a heat exchanger 278. Heat exchanger 278 can be an air-liquid heat exchanger through which coolant, which may be from a chiller system 280 which serves the facility within UPS 271 is disposed, flows. A pump 282 can pump the coolant from chiller system 280 through heat exchanger 278 and back to chiller system 280.

Heat exchanger 278 can be located inside, as shown, or outside (or some combination thereof) of the cabinet of UPS 271. Air flow 276 can be induced by a fan 284 or similar device, by way of non-limiting example. Air flow 276 can be air drawn from the cabinet or the room within which UPS 271 is disposed or can be outside ambient air. Air flow 276 after having flowed through heat exchanger 278 can be dumped into the cabinet or room containing UPS 271 or directed to a location external to the room and cabinet containing UPS 271.

Thus, in cooling system 270, air flow 276, in conjunction with heat-removal device 274, is utilized to remove heat from heat-generating device 272 and direct it into the coolant flowing through chiller system 280 that services the facility within which UPS 271 is utilized. The heat can be discharged to the ambient environment through chiller system 280.

Referring now to FIG. 10, still another cooling system 290 according to the present teachings is schematically illustrated. Cooling system 290 is a three-step process that transfers heat from the UPS 291 to an intermediary cooling system 302, which is subsequently transferred to a final cooling system 310 which may include the coolant flowing through chiller system 292 for the facility within which UPS 291 is located.

One or more (only one shown) heat-generating devices (components) 294 of UPS 291 are in heat-transfer relation, such as heat-conducting relation, with one or more (only one shown) heat-removal devices 296 which are in heat-transfer relation, such as heat-conducting relation, with an air flow 298. Heat-removal device 296 can be a heat sink (with or without fins), a heat pipe, and the like, by way of non-limiting example. Air flow 298 flows in heat-transfer relation with heat-removal device 296 and absorbs heat therefrom and transfers the heat to a heat-transfer fluid flowing through a heat exchanger 300 of a cooling system 302. The heat-transfer fluid of cooling system 302 can be water or refrigerant, by way of non-limiting example. A pump 304 circulates the heat-transfer fluid through heat exchanger 300 and through another heat exchanger 306. Preferably, the heat-transfer fluid remains in a single liquid phase throughout cooling system 302. Heat exchanger 300 can be an air-liquid heat exchanger that transfers heat from air flow 298 to the heat-transfer fluid. The heat-transfer fluid flowing through cooling system 302 is in heat-transfer relation with the coolant of cooling system 310 which also flows through heat exchanger 306. Heat exchanger 306 can be a liquid-liquid heat exchanger. A pump 308 can pump coolant from chiller system 292 through heat exchanger 306 and back to chiller system 292.

Heat exchangers 300, 306 and pump 304 may be located in (as shown), outside of, or some combination thereof of the cabinet of UPS 291. Additionally, heat exchangers 300, 306 can be disposed in different locations and may be located outside the room which houses UPS 291. A fan 312 or other air-moving device, by way of non-limiting example, can be utilized to induce air flow 298. Air flow 298 can be air drawn from the cabinet or the room within which UPS 291 is disposed or can be outside ambient air. Air flow 298 after flowing through heat exchanger 300 may be discharged into the cabinet or room containing UPS 291 or directed to a location external to the cabinet and room containing UPS 291.

It should be appreciated that in some embodiments, cooling system 302 can be a vapor compression cooling system that utilizes a compressor instead of a pump and may also include an expansion device. In that case, the heat-transfer fluid (e.g., refrigerant, volatile fluid, and the like, by way of non-limiting example) can be compressed and change phase.

Thus, in cooling system 290 air flow 298, via heat-removal device 296, transfers heat from heat-generating device 294 into the heat-transfer fluid flowing through cooling system 302. Heat absorbed by the heat-transfer fluid flowing through cooling system 302 is transferred to coolant in cooling system 310. This three-step process allows the heat removed from UPS 291 to be carried outside the cabinet and the room within which UPS 291 is disposed and transferred to the coolant flowing through chiller system 292 for discharge to the ambient environment.

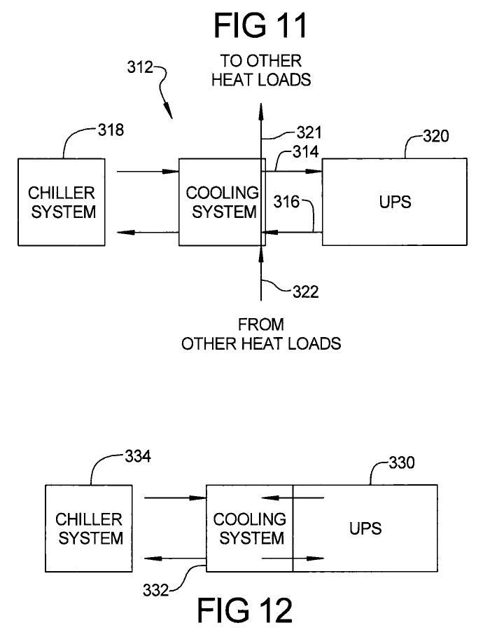

Referring now to FIG. 11, a simplified schematic representation of a UPS 320 and a cooling system 312 according to the present invention is shown. Cooling system 312 is external to UPS 320. Fluid flow lines 314, 316 allow a heat-transfer fluid to move from cooling system 312 through UPS 320 in heat-transferring relation to the heat-generating components of UPS 320. Heat generated by the heat-generating components of UPS 320 can be transferred to the heat-transfer fluid flowing through cooling system 312, which may be subsequently transferred to the coolant flowing through chiller system 318, which may be associated with the building or facility within which UPS 320 is utilized. It should be appreciated that within UPS 320, various flow paths and components necessary to allow the fluid flow from cooling system 312 to flow in and out via lines 314, 316 in heat-transferring relation with components of UPS 320 are included therein.

Cooling system 312 may also transfer heat from other heat loads, such as other UPSs, to chiller system 318. For example, as shown, a fluid supply line 320 may be utilized to direct the heat-transfer fluid of cooling system 312 to other heat loads while a fluid return line 322 may be utilized to return the heat-transfer fluid to cooling system 312 for subsequent heat transfer to chiller system 318. As such, a single cooling system 312 can be utilized to transfer the heat generated by multiple UPSs to a chiller system for the facility within which the UPSs are utilized. Chiller system 318 transfers the heat to the ambient environment.

Referring now to FIG. 12, a simplified schematic representation of a UPS 330 with an integral cooling system 332 according to the present invention is shown. Cooling system 332 is integral with UPS 330 and may be included in the same cabinet or may be two separate cabinets that are attached together. Cooling system 332 can route a heat-transfer fluid through UPS 330 in heat-transferring relation to the heat-generating components therein or through one or more heat-removal devices that extract heat from the heat-generating components within UPS 330. Cooling system 332 is operable to transfer the heat from the heat-generating components of UPS 330 to a chiller system 334 associated with the facility within which UPS 330 is utilized. Chiller system 334 can transfer the heat to the ambient environment. Thus, a cooling system for removing heat generated by the heat-generating components of a UPS can be integral therewith and disposed in the same cabinet as the UPS or be in another cabinet attached to the cabinet of the UPS such that they can be shipped and provide as a single integral module.

The inclusion of the various components that form the cooling systems for the associated UPS can facilitate the assembling and operation of the UPS in the room or facility within which it is to be utilized. In particular, the cooling system can be integral with the UPS such that the final cooling system associated with the chiller system can be easily connected thereto to provide the advantageous transferring of heat from the UPS to the ambient environment. The various components of the cooling systems can be internal to or external of (or a combination of both) the cabinet that forms the associated UPS.

It should be appreciated that cooling systems 120, 140, 180, 210, 230, 250, 270, 290, 312, 332 can be used in place of cooling system 38 and can remove heat Q₂ generated by the associated UPS from room 18. Additionally, a controller, such as controller 116 (along with flow regulators and the like), can be used to control operation of cooling systems 120, 140, 180, 210, 230, 250, 270, 290, 312, 332 in a manner similar to that discussed above with reference to cooling system 40 and coordinated with the removal of heat Q₁ from room 18 by air-conditioning system 19.

Thus, the cooling systems 38, 120, 140, 180, 210, 230, 250, 270, 290, 312, 332 according to the present disclosure can be utilized to provide cooling for the various components of an uninterruptible power supply and reduce the load on the air-conditioning system 19 that conditions the air in the room 18 within which the UPS is disposed. In this manner, a given size air-conditioning system 19 that conditions air in the room 18 can be utilized with varying size UPSs since the associated cooling system 38, 120, 140, 180, 210, 230, 250, 270, 290, 312, 332 for the UPS can remove heat Q₂ generated therefrom while reducing and/or eliminating changes in the demand placed on air-conditioning system 19. In some cases, it may be possible to use a smaller air-conditioning system 19 to condition the air in the room 18 when a cooling system 38, 120, 140, 180, 210, 230, 250, 270, 290, 312, 332 is utilized to remove heat from the UPS therein. Thus, the use of a cooling system 38, 120, 140, 180, 210, 230, 250, 270, 290, 312, 332 to remove heat from a UPS can advantageously reduce the load on the air-conditioning system 19 that conditions the air in the room within which the UPS is disposed.

It should be appreciated that, in the above descriptions of the various cooling systems 120, 140, 180, 210, 230, 250, 270, 290, 312, 332 an air flow can be induced across the transformers in the associated UPS and be transferred to the heat-transfer fluid in the associated cooling system for subsequent discharge to the ambient environment through the associated chiller system in a manner similar to that discussed above with reference to cooling system 40 and UPS 20. Moreover, it should be appreciated that, while the various cooling systems herein are described as utilizing a pump, in some cooling systems only a single pump is shown. However, redundant pumps in parallel, such as discussed above with reference to cooling system 38, can be utilized in the various cooling systems herein to provide a redundancy and uninterrupted supply of the heat-transfer fluid. Moreover, it should also be appreciated that, in some configurations, it may be possible to provide liquid cooling of the transformers. In such situations, the heat removal from the transformers associated with the UPS can be through a liquid heat-transfer fluid in lieu of the above-described air flow.

It should be appreciated that a UPS can include one or more rectifiers, inverters, static switches, and/or other components that can be cooled by a cooling plate and the cooling systems of the present teachings. Additionally, it should be appreciated that the heat could be collected from each component using heat pipe structures. The heat is collected at one end of the heat pipe and moved to the other end of the heat pipe to a condensing plate. The condensing plate is in thermal contact with another heat collection plate which is a part of a cooling loop. Heat transferred to this cooling loop can be dissipated to the coolant of a chiller system in a liquid-liquid heat exchanger.

Furthermore, it should be appreciated that the heat-transfer fluids described herein can take a variety of forms. For example, while some of the heat-transfer fluids are described as being a refrigerant, such fluids can also be water or a water-type fluid, by way of non-limiting example. Additionally, while the absorption of heat is described as causing the heat-transfer fluid to change states, it should be appreciated that in some embodiments, the heat-transfer fluid can remain in a single liquid state throughout the cooling process. Furthermore, it should be appreciated that the heat-transfer fluid can be an electrically non-conductive fluid or an electrically conductive fluid, as desired.

Moreover, it should be appreciated that while the various cooling systems and UPSs described herein are shown and described with reference to specific features and capabilities, these various features and capabilities can be mixed and matched with one another to produce a desired cooling system for a UPS. As such, the various features disclosed herein can be mixed and matched to provide the desired functionality. Accordingly, it should be understood that the preceding embodiments, descriptions, and depictions are merely exemplary in nature and that various changes to that shown and described can be made without deviating from the spirit and scope of the present teachings.

What is claimed is:

1. A method of transferring heat generated in an uninterruptible power supply to an environment external to the room or building housing the uninterruptible power supply, the uninterruptible power supply having a plurality of heat-generating components within a cabinet, the method comprising:
generating heat in the uninterruptible power supply with the plurality of heat-generating components;
pumping a first heat-transfer fluid through a first cooling circuit with a first liquid pump;
transferring heat from a first one of the heat-generating components in the cabinet to a first medium, the first medium being in direct heat-conducting relation with the first heat-generating component, and the first heat-generating component being at least one of a rectifier, an inverter, and a switch; and
transferring heat from the first medium to the first heat-transfer fluid;
transferring heat from the first heat-transfer fluid to the environment external to the room or building housing the uninterruptible power supply.

2. The method of claim 1, further comprising routing the first heat-transfer fluid in heat-transferring contact with the first medium and wherein transferring heat from the first medium to the first heat-transfer fluid includes transferring heat to the first heat-transfer fluid in heat-transferring contact with the first medium.

3. The method of claim 2, further comprising:
generating a first air flow through a portion of the cabinet with a first air flow generating device;
transferring heat from a second one of the heat-generating components in the cabinet to the first air flow, the second heat-generating component being a transformer, and the first air flow flowing in a heat-transferring relation across the transformer; and
transferring heat from the first air flow to the first heat-transferring fluid in a first heat-exchanging device, the first heat-exchanging device being a fluid-to-fluid heat-exchanging device.

4. The method of claim 2, further comprising transferring heat from a first group of multiple ones of the heat-generating components to the first medium, the heat-generating components of the first group each being in direct heat-conducting relation with the first medium, and the first group of heat-generating components each being one of a rectifier, an inverter, and a switch.

5. The method of claim 4, further comprising:
pumping a second liquid-heat-transfer fluid through a second cooling circuit with a second liquid pump;
transferring heat from the first heat-transfer fluid to the second heat-transfer fluid in a first heat-exchanging device; and
transferring heat from the second heat-transfer fluid to the environment external to the room or building housing the uninterruptible power supply, thereby transferring heat from the first heat-transfer fluid to the environment external to the room or building housing the uninterruptible power supply through the second cooling circuit.

6. The method of claim 2, further comprising:
pumping a second liquid-heat-transfer fluid through a second cooling circuit with a second liquid pump;
transferring heat from the first heat-transfer fluid to the second heat-transfer fluid in a first heat-exchanging device; and
transferring heat from the second heat-transfer fluid to the environment external to the room or building housing the uninterruptible power supply, thereby transferring heat from the first heat-transfer fluid to the environment external to the room or building housing the uninterruptible power supply through the second cooling circuit.

7. The method of claim 6, further comprising:
pumping a third liquid-heat-transfer fluid through a third cooling circuit with a third liquid pump;
transferring heat from the second heat-transfer fluid to the third heat-transfer fluid in a second heat-exchanging device; and
transferring heat from the third heat-transfer fluid to the environment external to the room or building housing the uninterruptible power supply, thereby transferring heat from the first heat-transfer fluid to the environment external to the room or building housing the uninterruptible power supply through the third cooling circuit.

8. The method of claim 6, wherein the first heat-exchanging device includes first and second plates in heat-conducting relation with one another and transferring heat from the first heat-transfer fluid to the second heat-transfer fluid includes routing the first heat-transfer fluid through the first plate, routing the second heat-transfer fluid through the second plate, and transferring heat from the first heat-transfer fluid to the second heat-transfer fluid through heat conduction between the first and second plates.

9. The method of claim 1, wherein:
pumping the first heat-transfer fluid includes pumping the first heat-transfer fluid through a second medium in heat-transferring relation thereto, the second medium being in heat-conducting relation to the first medium; and
transferring heat from the first medium to the first heat-transfer fluid includes conductively transferring heat from the first medium to the second medium and transferring heat from the second medium to the first heat-transfer fluid.

10. The method of claim 9, further comprising:
pumping a second liquid-heat-transfer fluid through a second cooling circuit with a second liquid pump;
transferring heat from the first heat-transfer fluid to the second heat-transfer fluid in a liquid-liquid heat-exchanging device; and
transferring heat from the second heat-transfer fluid to the environment external to the room or building housing the uninterruptible power supply, thereby transferring heat from the first heat-transfer fluid to the environment external to the room or building housing the uninterruptible power supply through the second cooling circuit.

11. The method of claim 1, further comprising transferring at least a majority of the heat generated by the rectifier, inverter, and switch of the uninterruptible power supply to the first heat-transfer fluid.

12. The method of claim 11, wherein transferring at least a majority includes transferring substantially all of the heat generated by the rectifier, inverter, and switch of the uninterruptible power supply to the first heat-transfer fluid.

13. An uninterruptible power supply system comprising:
a cabinet;
a plurality of heat-generating components in the cabinet, the heat-generating components including a rectifier, an inverter, a switch, and at least one transformer, the heat-generating components generating heat during operation;
a first heat-transfer medium in direct heat-conducting relation with at least one of the heat-generating components;
a first cooling circuit including a first heat-transfer fluid and a first flow-generating device generating a flow of the first heat-transfer fluid through the first cooling circuit;
a first heat-transfer flow path between the first medium and the first cooling circuit, the first heat-transfer flow path transferring heat from the first medium to the first heat-transfer fluid; and
a second heat-transfer flow path between the first cooling circuit and an ambient environment external to a room or building housing the cabinet, the second heat-transfer flow path transferring heat from the first heat-transfer fluid to the ambient environment external to the room or building housing the cabinet.

14. The uninterruptible power supply system of claim 13, wherein the first heat-transfer fluid is a liquid and the first flow-generating device is a first liquid pump generating a flow the first liquid heat-transfer fluid through the first cooling circuit.

15. The uninterruptible power supply system of claim 14, wherein the first heat-transfer flow path includes direct heat-transferring contact between the first heat-transfer fluid and the first medium.

16. The uninterruptible power supply system of claim 15, further comprising:
an air flow generating device generating an air flow across the at least one transformer, the air flow extracting heat from the at least one transformer; and
a first fluid-to-fluid heat-exchanging device through which the air flow and the first heat-transfer fluid flow, the first heat-exchanging device transferring heat from the air flow to the first heat-transfer fluid. uninterruptible

17. The uninterruptible power supply system of claim 15, wherein multiple ones of the heat-generating components are in direct heat-conducting relation with the first heat-transfer medium.

18. The uninterruptible power supply system of claim 17, further comprising:
a second cooling circuit including a second liquid heat-transfer fluid and a second liquid pump generating a flow of the second heat-transfer fluid through the second cooling circuit, and
wherein the second heat-transfer flow path includes a first fluid-to-fluid heat-exchanging device through which the first and second heat-transfer fluids flow, the first heat-exchanging device transferring heat from the first heat-transfer fluid to the second heat-transfer fluid for subsequent discharge to the environment external to the room or building housing the cabinet.

19. The uninterruptible power supply system of claim 15, further comprising:
a second cooling circuit including a second liquid heat-transfer fluid and a second liquid pump generating a flow of the second heat-transfer fluid through the second cooling circuit, and
wherein the second heat-transfer flow path includes a first heat-exchanging device through which the first and second heat-transfer fluids flow, the first heat-exchanging device transferring heat from the first heat-transfer fluid to the second heat-transfer fluid for subsequent discharge to the environment external to the room or building housing the cabinet.

20. The uninterruptible power supply system of claim 19, further comprising:
a third cooling circuit including a third liquid heat-transfer fluid and a third liquid pump generating a flow of the third heat-transfer fluid through the third cooling circuit, and
wherein the second heat-transfer flow path includes a second fluid-to-fluid heat-exchanging device through which the second and third heat-transfer fluids flow, the second heat-exchanging device transferring heat from the second heat-transfer fluid to the third heat-transfer fluid for subsequent discharge to the environment external to the room or building housing the cabinet.

21. The uninterruptible power supply system of claim 19, wherein the first heat-exchanging device includes first and second plates in heat-conducting relation with one another, the first heat-transfer fluid flowing through the first plate, the second heat-transfer fluid flowing through the second plate, and the first plate transferring heat from the first heat-transfer fluid to the second plate and the second plate transferring heat from the second plate to the second heat-transfer fluid.

22. The uninterruptible power supply system of claim 14, wherein the first heat-transfer flow path includes a second heat-transfer medium through which the first heat-transfer fluid flows in heat-conducting relation, the second heat-transfer medium being in heat-conducting relation to the first heat-transfer medium, and the first heat-transfer flow path transferring heat from the first medium to the second medium and from the second medium to the first heat-transfer fluid.

23. The uninterruptible power supply system of claim 22, further comprising:
a second cooling circuit including a second liquid heat-transfer fluid and a second liquid pump generating a flow of the second heat-transfer fluid through the second cooling circuit, and
wherein the second heat-transfer flow path includes a liquid-liquid heat-exchanging device through which the first and second heat-transfer fluids flow, the heat-exchanging device transferring heat from the first heat-transfer fluid to the second heat-transfer fluid for subsequent discharge to the environment external to the room or building housing the cabinet.

24. The uninterruptible power supply system of claim 14, wherein the first heat-transfer flow path includes an air-flow generating device and a first heat-exchanging device, the air-flow generating device generating an air flow across at least one of the heat-generating devices and across the first heat-exchanging device, the first heat-exchanging device having the first heat-transfer fluid flowing therethrough, and the air flow transferring heat from the at least one heat-generating component to the first heat-transfer fluid through the first heat-exchanging device and uninterruptible further comprising:
a second cooling circuit including a second heat-exchanging device, a second liquid heat-transfer fluid, and a second liquid pump generating a flow of the second heat-transfer fluid through the second cooling circuit, the first and second heat-transfer fluids flowing through the second heat-exchanging device, and the heat-exchanging device transferring heat from the first heat-transfer fluid to the second heat-transfer fluid for subsequent discharge to the environment external to the room or building housing the cabinet.

25. The uninterruptible power supply system of claim 13, wherein the second heat-transfer flow path includes a chiller system.

26. The uninterruptible power supply system of claim 13, wherein the ambient environment is subterranean earth and the second heat-transfer flow path includes a heat-transfer flow path between the first cooling circuit and the subterranean earth.

27. The uninterruptible power supply system of claim 13, wherein at least a majority of the heat generated by the rectifier, inverter, and switch is transferred to the ambient environment by-passing an air flow flowing through and conditioning the room housing the uninterruptible power supply.

28. The uninterruptible power supply system of claim 28, wherein substantially all of the heat generated by the rectifier, inverter, and switch is transferred to the ambient environment by-passing the air flow flowing through and conditioning the room housing the uninterruptible power supply.
